(19) United States
(12) Patent Application Publication
(10) Pub. No.: US 2006/0230327 A1
(43) Pub. Date: Oct. 12, 2006

(54) Apparatus for and method of recording digital information signals

(75) Inventors: Johannis Friso Rendert Blacquiere, Eindhoven (NL); Pope Ijtsma, Eindhoven (NL); Dirk Hamelinck, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/564,909

(22) PCT Filed: Jul. 13, 2004
(86) PCT No.: PCT/IB04/51204

§ 371 Date: Jan. 17, 2006

(30) Foreign Application Priority Data
Jul. 17, 2003 (EP) 03102206.4

(51) Int. Cl. G11C 29/00

(52) U.S. Cl. 714/763

(57) ABSTRACT

A recording apparatus for recording digital information signals on a removable rewritable disc like recording medium has been proposed. The apparatus comprises writing means (21, 22, 25) for recording the digital information signals and controls means (20) for controlling the recording. The apparatus is capable of performing initialization, formatting and defect management of a rewritable medium. Further, the apparatus is capable of storing first file system data in a user area (UA) and second file system data in a general application area (GAA) on the medium. The control means (20) are adapted to modify defect management data on the medium in order to block write access to UA under control of the first file system. This prevents systems unaware of the second file system data on the medium from modifying contents of UA.

The invention relates to a recording apparatus for recording digital information signals on a removable rewritable disc like recording medium, the medium comprising a user area comprising user data represented by the digital information signals and a table area outside the user area comprising a defect table, the defect table comprising defect management data having a predefined data format, the defect management data related to defect areas in the user area and replacement areas on the medium, the recording apparatus comprising

input means for receiving the digital information signals;

recording means for recording the digital information signals on the medium;

reading means for reading recorded digital information signals recorded on the medium;

output means for outputting the read digital information signals;

control means for controlling recording the digital information signals.

The invention further relates to a method of protecting digital information signals recorded on a removable rewritable disc like recording medium, the medium comprising a user area comprising user data represented by the digital information signals and a table area outside the user area comprising a defect table, the defect table comprising defect management data having a predefined data format, the defect management data related to defect areas in the user area and replacement areas on the medium.

The invention also relates to a computer data system comprising a computer connected to a recording apparatus for recording digital information signals on a removable rewritable disc like recording medium, the medium comprising a user area comprising user data represented by the digital information signals and a table area outside the user area comprising a defect table, the defect table comprising defect management data having a predefined data format, the defect management data related to defect areas in the user area and replacement areas on the medium, the recording apparatus comprising

input means connected to the computer for receiving the digital information signals;

recording means for recording the digital information signals on the medium;

reading means for reading recorded digital information signals recorded on the medium;

output means for outputting the read digital information signals to the computer;

control means for controlling recording the digital information signals.

The invention further relates a computer program product for recording digital information signals on a removable rewritable disc like recording medium.

Recording media like optical discs (DVD+RW, Blu-Ray, etc.) are capable of storing large amount of data of different types. They can be used in different environments having specific requirements as for organization of data on a recording medium. Typically, data are organized into files in accordance with rules of a particular file system. Such file system has its own file system data, which include information about all kind of structures relating to data stored on a recording medium. In particular, file system data may include volume structures representing the structures of logical and/or physical volumes, file structures representing the structures of files containing the data, directory structures describing grouping of files, and a space bitmap representing allocated or unallocated space for storing data on a recording medium. A recording medium may comprise addressable recording units for storing the data. At a level of a file system those units are referenced to with use of logical addresses defining addressing space. Partitioning of a recording medium allocates a space on the medium for storing data under control (according to rules) of a file system.

At present, for example, DVD+RW discs are in use by Consumer Electronics (CE) devices and in the Personal Computer (PC) environment. In the CE environment DVD+RW discs are used mainly for recording digital video information according to a format of DVD Video Recording, commonly referred to as DVD+VR. This means that there are defined specific allocation rules and set of files containing the video information itself and information about that video information such as title information, menu structures, etc. For example, in the DVD+VR format some files start at fixed addresses. Next to that the (predefined) list of files has to be physically on a medium in a certain order.

The PC environment is based on a different philosophy. There are, in principle, no allocation requirements. Specific applications may require some files to be present in a certain directory and applications will typically have their own data format to store information in files or to retrieve information from a file. This means that as long as there is free space available on a medium it is possible to add data files to that medium from all kinds of different applications. As an example, on a single disc there could be multi-media files, text files and executable files all mixed with each other.

Recently, more and more CE devices, like video players/recorders, have capability to seek through the file system information on the disc for files of a certain type that they can handle as well. Example of this are (mainly) JPEG files and also, already more and more, MP3 files. In the future possibly more types of multi-media files will be supported in the CE world. Next to that, also new standards on meta-data are created (such as e.g. MPV or HighMAT) designed to make it easier to move digital content between PCs and home electronics devices, e.g. by providing a common “look and feel” in different environments.

The published international patent application WO 01/22416 A1 discloses the recording apparatus capable of performing initialization, formatting and defect management of a rewritable medium such as a CD-RW disc. This is done to facilitate the use of CD-RW as a high-capacity floppy disc, so immediate writing or reading of files is possible. Such media are commonly referred to as Mount Rainier ReWritable (MRW) media, e.g. CD-MRW, DVD+MRW.

Further, said recording apparatus makes it possible to store file system data of different file systems on one recording medium, so-called “bridge medium”. This facilitates sharing of the bridge medium between different environments, e.g. the CE environment and the PC environment. A special part of a recording medium, called a general application area (GAA), is allocated for storing file system data of a file system used by other devices not capable of performing the defect management in line with WO 01/22416 A1. In case of DVD+MRW media, GAA has a size of 2 MBytes.

In the PC environment the most likely way of adding data to the bridge medium is by means of “drag-and-drop” technique. A user can then make the medium compatible with legacy players through the use of a compliance (bridge) application running on the PC. Basically, the application writes a second (“limited”) file system data, called “CE-bridge”, to the medium, using the suitable file system(s) and content pointers, such that a legacy “non-MRW” system can interpret these as content under its main file system. As a result, the CE-player will play the content that is referenced by this file system data, for which it has suitable content decoders. When the bridge medium is used in a non-MRW PC-drive, the GAA file system is mounted by the host and “drag-and-drop” is not possible.

A problem arises when the bridge medium is used in a MRW system, which has no knowledge of CE-bridge structures. In such system the user can change the content in the user area on the medium and in that case the CE-bridge is not up to date with the newest status of CE-playable content.

It is an object of the invention to improve exchangeability of the bridge medium between environments using the CE-bridge and MRW environments.

This object is achieved, according to a first aspect of the invention, by a recording apparatus of the type described in the opening paragraph, characterized in that the control means are adapted to read the defect table from the medium, to modify the defect management data comprised in the defect table read in order to block write access to the user area according to predefined defect management rules and to record the defect table comprising modified defect management data on the medium. This prevents MRW devices not capable of updating the CE-bridge from modifying the content of the user area on such medium, making use of the defect management rules. In this way the CE-bridge structures are maintained up to date with the content of the user area.

In an embodiment of the recording apparatus, the control means are adapted to search the defect management data comprised in the defect table read for free replacement area addresses of all free replacement areas without the user data and to modify the defect management data by marking the all free replacement areas as unusable. This ensures that, neither new data are recorded in the user area nor existing data are modified, as the defect management rules block write access to the user area in such case.

In a further embodiment of the recording apparatus, the control means are adapted to modify the defect management data comprised in the defect table read with respect to primary defect management data comprised in a primary defect table on the medium, the defect table being a copy of the primary defect table, so the defect management data comprised in the defect table are inconsistent with the primary defect management data. This embodiment is advantageous in that it blocks write access to the user area by deliberately introducing inconsistencies between the primary defect table and its copy.

In another embodiment of the recording apparatus, the control means are adapted to modify a copy of a primary update counter data comprised in the defect management data with respect to the primary update counter data comprised in the primary defect management data. This introduces a specific inconsistency between the two defect tables.

It is advantageous, if the control means are adapted to generate protection data comprising information related to modification of the defect management data and to record the protection data on the medium. The protection data may be used to notify other system and/or a user that the defect management data on the medium was modified in order to block write access.

In yet another embodiment of the recording apparatus, the control means are adapted to read the protection data and the defect table comprising the modified defect management data from the medium, to restore the defect management data from the modified defect management data using the protection data in order to resume write access to the user area according to the predefined defect management rules and to record the defect table comprising the defect management data on the medium. This embodiment is advantageous in that it is capable of restoring write access to the user area on the medium, which defect management data were previously modified in order to block write access.

According to a second aspect of the invention a method of protecting digital information signals recorded on a removable rewritable disc like recording medium of the type described in the opening paragraph is provided characterized by reading the defect table from the medium;

modifying the defect management data comprised in the defect table read in order to block write access to the user area according to predefined defect management rules;

recording the defect table comprising modified defect management data on the medium.

According to a third aspect of the invention a computer data system of the type described in the opening paragraph is provided, characterized in that the computer is adapted to control the control means of the recording apparatus to perform the method as described in relation to the second aspect of the invention.

According to a forth aspect of the invention a computer program product for protecting digital information signals recorded on a removable rewritable disc like recording medium is provided, which program is operative to cause a processor to perform the method as described in relation to the second aspect of the invention.

These and other aspects of the invention will be apparent from and elucidated further with reference to the embodiments described by way of example in the following description and with reference to the accompanying drawings, in which:

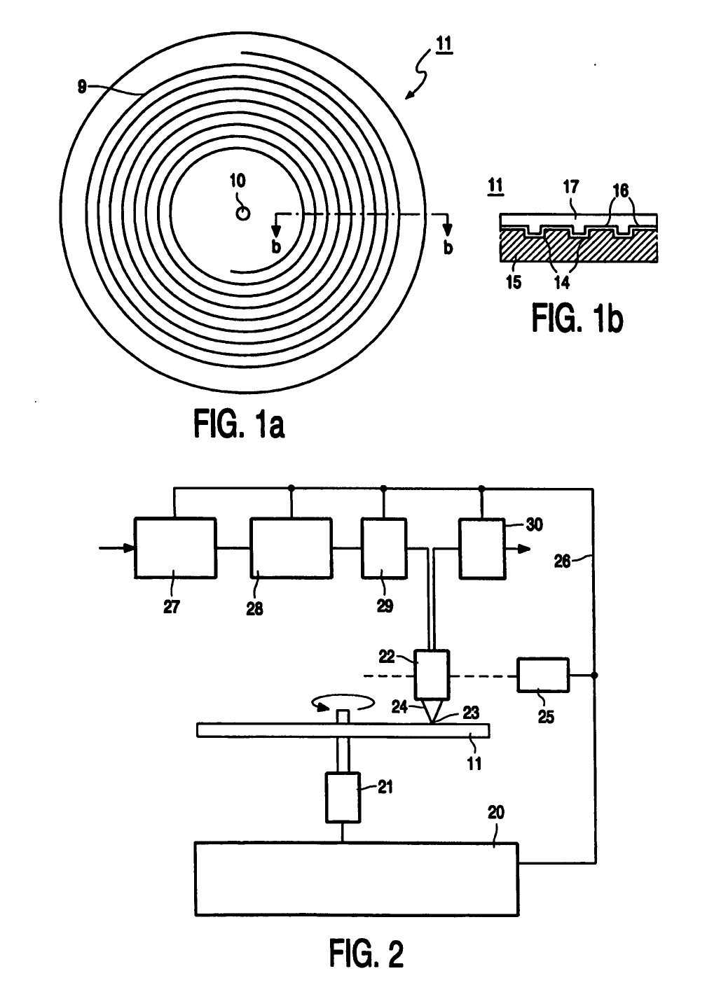

FIG. 1a shows a recording medium (top view),

FIG. 1b shows a recording medium (cross section),

FIG. 2 shows a recording apparatus, in accordance with the invention,

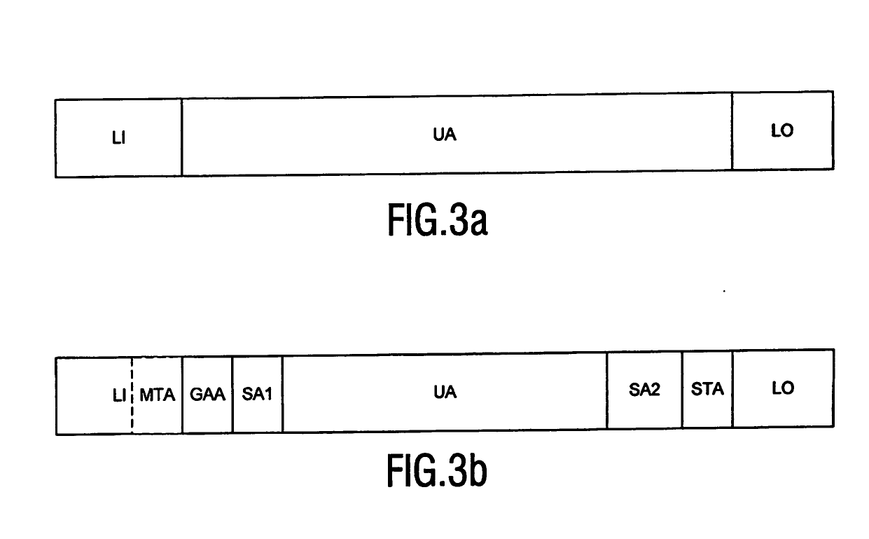

FIG. 3a shows a simplified layout of a non-MRW type of medium,

FIG. 3b shows a simplified layout of a MRW type of medium,

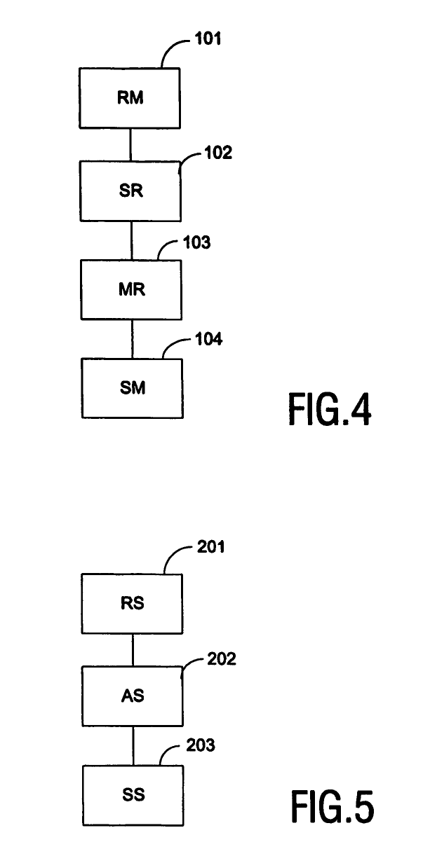

FIG. 4 shows an example of a method of blocking write access to the user area using a list of replacement areas, in accordance with the invention.

FIG. 5 shows an example of a method of blocking write access to the user area by creating inconsistencies between defect tables, in accordance with the invention.

Corresponding elements in different Figures have identical reference numerals.

FIG. 1a shows an example of a recording medium 11 having a form of disc with a track 9 and a central hole 10. The track 9, being the position of the series of (to be) recorded marks representing digital information signals (data), is arranged in accordance with a spiral pattern of turns constituting substantially parallel tracks on an information layer. The recording medium may be optically readable, called an optical disc, and has an information layer of a recordable type. Examples of a recordable disc are the CD-RW, and writable versions of DVD, such as DVD+RW, and the high density writable optical disc using blue lasers, called Blu-ray Disc (BD). Digital information signals (data) are represented on the information layer by recording optically detectable marks along the track, e.g. crystalline or amorphous marks in phase change material. The track 9 on the recordable type of recording medium is indicated by a pre-embossed track structure provided during manufacture of the blank recording medium. The track structure is constituted, for example, by a pregroove 14, which enables a read/write head to follow the track during scanning. The track structure comprises position information, e.g. addresses, for indication the location of units of information, usually called information blocks or packets.

FIG. 1b is a cross-section taken along the line b-b of the recording medium 11 of the recordable type, in which a transparent substrate 15 is provided with a recording layer 16 and a protective layer 17. The protective layer 17 may comprise a further substrate layer, for example as in DVD where the recording layer is at a 0.6 mm substrate and a further substrate of 0.6 mm is bonded to the back side thereof. The pregroove 14 may be implemented as an indentation or an elevation of the substrate 15 material, or as a material property deviating from its surroundings.

FIG. 2 shows a recording apparatus for recording digital information signals a recording medium 11 such as CD-RW, DVD+RW or BD, in accordance with the invention. The apparatus is provided with writing means for scanning the track on the recording medium, which means include a drive unit 21 for rotating the recording medium 11, a head 22, and a positioning unit 25 for coarsely positioning the head 22 in the radial direction on the track. The head 22 comprises an optical system of a known type for generating a radiation beam 24 guided through optical elements focused to a radiation spot 23 on a track of the information layer of the recording medium. The radiation beam 24 is generated by a radiation source, e.g. a laser diode. The head further comprises (not shown) a focusing actuator for moving the focus of the radiation beam 24 along the optical axis of said beam and a tracking actuator for fine positioning of the spot 23 in a radial direction on the center of the track. The tracking actuator may comprise coils for radially moving an optical element or may alternatively be arranged for changing the angle of a reflecting element. For writing digital information signals (data) the radiation is controlled to create optically detectable marks in the recording layer. The marks may be in any optically readable form, e.g. in the form of areas with a reflection coefficient different from their surroundings, obtained when recording in materials such as dye, alloy or phase change material, or in the form of areas with a direction of magnetization different from their surroundings, obtained when recording in magneto-optical material. For reading, the radiation reflected by the information layer is detected by a detector of a usual type, e.g. a four-quadrant diode, in the head 22 for generating a read signal and further detector signals including a tracking error and a focusing error signal for controlling said tracking and focusing actuators. The read signal is processed by read processing unit 30 of a usual type including a demodulator, deformatter and output unit to retrieve the digital information signals (data). Hence retrieving means for reading information include the drive unit 21, the head 22, the positioning unit 25 and the read processing unit 30. The apparatus comprises write processing means for processing the input digital information signals (data) to generate a write signal to drive the head 22, which means comprise an input unit 27, and modulator means comprising a formatter 28 and a modulator 29. The input digital information signals (data) may comprise for example real-time video and/or audio data or still images data. The input unit 27 processes the input data to units of information, which are passed to the formatter 28 for adding control data and formatting the data, e.g. by adding error correction codes (ECC) and/or interleaving. For computer applications units of information may be interfaced to the formatter 28 directly—in such case, as an option, the input unit 27 does not have to be present in the apparatus. The formatted data from the output of the formatter 28 is passed to the modulation unit 29, which comprises for example a channel coder, for generating a modulated signal, which drives the head 22. Further the modulation unit 29 comprises synchronizing means for including synchronizing patterns in the modulated signal. The formatted units presented to the input of the modulation unit 29 comprise address information and are written to corresponding addressable locations on the recording medium under the control of control unit 20. Further, the apparatus comprises a control unit 20, which controls the recording and retrieving of information and may be arranged for receiving commands from a user or from a host computer. The control unit 20 is connected via control lines 26, e.g. a system bus, to said input unit 27, formatter 28 and modulator 29, to the read processing unit 30, and to the drive unit 21, and the positioning unit 25. The control unit 20 comprises control circuitry, for example a microprocessor, a program memory and control gates, for performing the procedures and functions according to the invention as described below. The control unit 20 may also be implemented as a state machine in logic circuits.

The control unit 20 is capable of performing initialization, formatting and defect management of a rewritable medium such as a DVD+RW disc. An example of simplified layout of such disc is shown in FIG. 3b. It comprises lead-in area LI, lead-out area LO, a general application area GAA, a spare area SA (in this example comprising two sub-areas SA1 and SA2), a user area UA, and table areas MTA and STA. LI and LO contain mainly media read/write definition and administration data. The user area UA is used mainly for recording of data used for real use and data related to content stored on a recording medium, such as user data and first file system data comprising directory and file entries pointing to the user data according to rules of a first file system. The general application area GAA can be used for storage of data that does not allow replacements by the defect management, such as application programs or device drivers that can handle defects, or file system data of additional file systems. The defect management is based on a main defect table MDT stored in a main table area MTA, a secondary defect table SDT stored in a secondary table area STA and replacement areas (packets) comprised in the spare area SA1, SA2. The secondary defect table is a copy of the main defect table; SDT contains the same information as MDT. It only needs to be updated when the medium is ejected from a recorder. STA is used as redundancy in case of issues with MTA, and for assuring that non-MRW PC-systems can use these tables for address remapper in order to logically construct the address space, compensating for the defect management reallocation (not interpretable by non-MRW drives). The main table area MTA is located within the lead-in area LI. Recording media with a layout of the type shown in FIG. 3b are commonly referred to as Mount Rainier ReWritable (MRW) media, e.g. CD-MRW or DVD+MRW, in contrast to “non-MRW” media with a layout as in example shown in FIG. 3a. In case of DVD+MRW recording media, GAA, SA1 and SA2 have a size of 2, 8 and 120 (or 504) MBytes, respectively.

Based on the MRW definitions, it is possible to ensure that MRW media can be read by non-MRW capable drives, by installing a remapping driver on the PC. This remapping driver can be obtained easily, amongst other, by using GAA, such that the file system in GAA launches an application, which installs this driver or downloads it from the Internet. For convergence with non-MRW aware CE devices, the same or a different file system, (typically ISO9660 or UDF) can be used for allowing addressing of the content typically recognized by CE devices. This is done by pointing to the multimedia content stored in UA of the MRW medium, using file system data stored in GAA, hereinafter also referred to as second file system data, known by CE devices. There can be an extra file system in GAA, dedicated to performing tasks related to the remapping driver.

The defect management employs predefined rules for determining defective areas in UA, for organizing spare areas on a medium, for defining circumstances under which data can be recorded/modified on the medium, generally, for controlling storing information on the medium. A defect table contains information, which can be used to perform the defect management. In particular, the defect table contains a list of defective areas (packets), which have been determined to be defective during verification or during use of the medium, according to rules of the defect management. Further, it contains a list of replacement areas (packets), to be used as replacements of defective areas. The format of defect management data in the defect table is defined in the defect management rules. Defective and replacement areas are referred to by their addresses on the medium. Different flags or status bits within the defect table indicate characteristics of those areas, e.g. usability for data recording. The defect table also contains information related to areas on the medium, where the defect management shall not be active, such as a size and position of GAA.

The control unit 20 is adapted to read the defect table from the medium, to modify defect management data comprised in the defect table read in order to block write access to UA according to the defect management rules and to record the defect table comprising modified defect management data back on the medium.

In an embodiment, the control unit 20 is capable of setting all free replacement entries in the MRW defect table to unusable, making the medium read-only because the medium has run out of spare area and the defect management requires MRW drives to disable writing capabilities to such discs.

A particular method performed by the control unit 20 of an embodiment of the apparatus, is shown in FIG. 4.

In step 101, MDT is read from a disc, then a list of addresses of replacement areas is searched for free replacement area addresses of all free replacement areas without the user data (step 102). Next, in step 103, the all free replacement areas are marked as unusable in MDT. Finally, MDT is recorded back on the disc in step 104.

In another embodiment of the apparatus, the control unit 20 is capable to invalidate one or more of the structures in SDT. This forces the MRW drive to go to read-only mode as required by the MRW specification in case of issues with defect tables consistency.

Specifically, in an advantageous embodiment, the control unit 20 is adapted to perform a method as shown in FIG. 5.

In step 201, SDT is read from a disc. Consequently, defect management data comprised in SDT is altered in step 202, so SDT is no longer an exact copy of MDT. The point is to create inconsistencies between MDT and SDT. SDT comprising the altered defect management data is then recorded back on the disc, in step 203.

For example, a value of an update counter in SDT can be made different from a corresponding update counter in MDT, in step 202. These counters are related to changes/updates made to defect tables.

MDT can be recorded in MTA as a Main Information Packet (MIP) and at least two Main Defect Table Packets (MDTPO and MDTPI). In such case, SDT comprise a Secondary Information Packet (SIP) and Secondary Defect Table Packets (SDTPO and SDTPI) corresponding to MIP, MDTPO and MDTPI, respectively. All packets of SDT have the same contents as the corresponding packets of MDT. MIP and SIP contain the basic information about the defect management structures on the medium, such as number and locations of Main/Secondary Defect Tables Packets, and sizes of GAA, SA1 and SA2. A list of defect areas, which have been determined to be defective during verification or during use of the medium, and a list of replacement areas reserved for replacements are comprised in MDTPO and MDTPI.

In an embodiment, the control unit 20 is adapted to modify data comprised in MDT so only MIP and MDTPO contain information, which is recognizable by the defect management, i.e. has a format defined by the defect management rules. For example, data in MDTPI can be corrupted by filling it only with binary zeros. At the same time, data in SDT are not modified. This will allow other MRW devices to recover the original information comprised in MDT using SDT. However, in accordance with the MRW specification, the medium will be mounted as read-only by those devices. In addition, the control unit 20 can be modified to set all free replacement entries in MDTPO and SDT to unusable. This will provide even stronger protection against writing on the medium as the recovered information in MDT will indicate that the medium has run out of spare area.

The control unit 20 can be adapted to set directories/files in the UA file system data to read-only. This can be done selectively per file or per directory, e.g. only the content the video player can playback like the video_merge_ts directories are set to read-only. This function can be performed as a respond to a user command or automatically, for example using a pre-defined set of file types, file systems characteristics or other conditions.

Advantageously, the control unit 20 is adapted to combine the above methods of blocking write access to UA to optimize the end result. A key reason for such combination is to avoid maximally use-experience issues. For example some drives may have capability to write to read-only files or directories, or to restore further writing by recovering invalidated defect table entries, or to write without any free replacement entries, or to restore write capability to discs with defect tables consistency issues.

In an embodiment of the apparatus, the control unit 20 is adapted to generate protection data comprising information related to modification of defect management data in MDT or SDT and to record this information on a medium.

For example, the protection information may comprise an auto-run application stored in GAA, which, when launched on non-MRW legacy systems, warns a user that the medium contains content suitable for CE playback and should not be written without use of a special application and/or an upgraded device. Using the same or another auto-run application a user can be notified that this is a special disc, needing a special application and/or drives to enable writing to the disc, in such a way that CE bridge is kept consistent with the content changes, in case of MRW capable systems without the bridge functionality.

In another example, the protection information comprises information describing changes made to defect management data or to the UA file system data stored on a disc in order to block write access to UA.

In an embodiment, the control unit 20 is adapted to resume write access to UA by restoring original defect management data using the protection information. This can be done e.g. by a special command requesting the apparatus to restore write access to this disc by recovering invalidated spares, replacement areas. The control unit 20 is also capable of restoring consistency of data between MDT and SDT. If necessary, directories/files in the UA file system data can be set back to writable. Also, the control unit 20 is capable of suppressing the above described auto-run applications or “hiding” this part of file system to the operating system. After the write updates to the disc, the control unit 20 can bring the disc back to the same “read-only” state, as the disc came into the apparatus, but now reflecting the updated CE bridge in GAA.

In an embodiment, the recording apparatus is arranged as a drive unit to be connected to a separate host system, for example a drive unit to be build in a PC. The control unit 20 is arranged to communicate with a processing unit in the host system via a standardized interface.

In an embodiment of a computer data system comprising the host system and the recording apparatus, the processing unit in the host system is adapted to control the control unit 20 to perform methods and functions as described in reference to embodiments of the recording apparatus presented above.

A computer program product according to the invention is operative to cause the control unit 20 or the processing unit to perform methods and functions as described in reference to embodiments of the recording apparatus presented above.

Whilst the invention has been described with reference to preferred embodiments thereof, it is to be understood that these are not limitative examples. Thus, various modifications may become apparent to those skilled in the art, without departing from the scope of the invention, as defined by the claims. Further, the invention lies in each and every novel feature or combination of features described above. Also, for the storage medium an optical disc has been described, but other media, such as a magneto-optical disc or magnetic tape, can be used. It is noted, that the invention may be implemented by means of a general purpose processor executing a computer program or by dedicated hardware or by a combination of both, and that in this document the word “comprising” does not exclude the presence of other elements or steps than those listed and the word “a” or “an” preceding an element does not exclude the presence of a plurality of such elements, that any reference signs do not limit the scope of the claims, that “means” may be represented by a single item or a plurality and that several “means” may be represented by the same item of hardware.

1. A recording apparatus for recording digital information signals on a removable rewritable disc like recording medium, the medium comprising a user area comprising user data represented by the digital information signals and a table area outside the user area comprising a defect table, the defect table comprising defect management data having a predefined data format, the defect management data related to defect areas in the user area and replacement areas on the medium, the recording apparatus comprising
input means for receiving the digital information signals;
recording means for recording the digital information signals on the medium;
reading means for reading recorded digital information signals recorded on the medium;
output means for outputting the read digital information signals;
control means for controlling recording the digital information signals, characterized in that
the control means are adapted to read the defect table from the medium, to modify the defect management data comprised in the defect table read in order to block write access to the user area according to predefined defect management rules and to
record the defect table comprising modified defect management data on the medium.

2. A recording apparatus as claimed in claim 1, the defect management data comprising a list of addresses of the replacement areas, characterized in that
the control means are adapted to search the list of addresses of the replacement areas comprised in the defect table read for free replacement area addresses of all free replacement areas without the user data and to
modify the defect management data by marking the all free replacement areas as unusable.

3. A recording apparatus as claimed in claim 1, characterized in that the control means are adapted to replace a part of the defect management data by data having a format different from the predefined data format.

4. A recording apparatus as claimed in claim 1, the medium comprising a primary defect table, the defect table being a copy of the primary defect table, characterized in that the control means are adapted to modify the defect management data comprised in the defect table read with respect to primary defect management data comprised in the primary defect table, so the defect management data comprised in the defect table are inconsistent with the primary defect management data.

5. A recording apparatus as claimed in claim 4, the primary defect management data comprising primary update counter data related to updates of the primary defect table, characterized in that the control means are adapted to modify a copy of the primary update counter data comprised in the defect management data with respect to the primary update counter data.

6. A recording apparatus as claimed in claim 1, characterized in that the control means are adapted to generate protection data comprising information related to modification of the defect management data and to record the protection data on the medium.

7. A recording apparatus as claimed in claim 6, characterized in that
the control means are adapted to read the protection data and the defect table comprising the modified defect management data from the medium, to
restore the defect management data from the modified defect management data using the protection data in order to resume write access to the user area according to the predefined defect management rules and to
record the defect table comprising the defect management data on the medium.

8. A method of protecting digital information signals recorded on a removable rewritable disc like recording medium, the medium comprising a user area comprising user data represented by the digital information signals and a table area outside the user area comprising a defect table, the defect table comprising defect management data having a predefined data format, the defect management data related to defect areas in the user area and replacement areas on the medium, the method characterized by
reading the defect table from the medium;
modifying the defect management data comprised in the defect table read in order to block write access to the user area according to predefined defect management rules;
recording the defect table comprising modified defect management data on the medium.

9. A method as claimed in claim 8, the defect management data comprising a list of addresses of the replacement areas, characterized by
searching the list of address of the replacement areas comprised in the defect table read for free replacement area addresses of all free replacement areas without the user data and
modifying the defect management data by marking the all free replacement areas as unusable.

10. A method as claimed in claim 8, characterized by replacing a part of the defect management data by data having a format different from the predefined data format.

11. A method as claimed in claim 8, the medium comprising a primary defect table, the defect table being a copy of the primary defect table, characterized by modifying the defect management data comprised in the defect table read with respect to primary defect management data comprised in the primary defect table, so the defect management data comprised in the defect table are inconsistent with the primary defect management data.

12. A method as claimed in claim 11, the primary defect management data comprising primary update counter data related to updates of the primary defect table, characterized by modifying a copy of the primary update counter data comprised in the defect management data with respect to the primary update counter data.

13. A method as claimed in claim 8, characterized by
generating protection data comprising information related to modification of the defect management data;
recording the protection data on the medium.

14. A method as claimed in claim 13, characterized by
reading the protection data and the defect table comprising the modified defect management data from the medium;
restoring the defect management data from the modified defect management data using the protection data in order to resume write access to the user area according to the predefined defect management rules;
recording the defect table comprising the defect management data on the medium.

15. A computer data system comprising a computer connected to a recording apparatus for recording digital information signals on a removable rewritable disc like recording medium, the medium comprising a user area comprising user data represented by the digital information signals and a table area outside the user area comprising a defect table, the defect table comprising defect management data having a predefined data format, the defect management data related to defect areas in the user area and replacement areas on the medium, the recording apparatus comprising
input means connected to the computer for receiving the digital information signals;
recording means for recording the digital information signals on the medium;
reading means for reading recorded digital information signals recorded on the medium;
output means for outputting the read digital information signals to the computer;
control means for controlling recording the digital information signals, characterized in that the computer is adapted to control the control means of the recording apparatus to perform the method according to claim 8.

16. A computer program product for protecting digital information signals recorded on a removable rewritable disc like recording medium, which program is operative to cause a processor to perform the method according to claim 8.
